(19) United States
(12) Patent Application Publication
(10) Pub. No.: US 2021/0182721 A1
(43) Pub. Date: Jun. 17, 2021

(54) METHOD AND APPARATUS FOR CONSTRUCTING QUANTUM MACHINE LEARNING FRAMEWORK, QUANTUM COMPUTER AND COMPUTER STORAGE MEDIUM

(71) Applicant: ORIGIN QUANTUM COMPUTING COMPANY, LIMITED, HEFEI, Hefei, Anhui (CN)

(72) Inventors: Ye LI, Hefei, Anhui (CN); Menghan DOU, Hefei, Anhui (CN)

(21) Appl. No.: 16/624,001

(22) PCT Filed: May 8, 2019
(86) PCT No.: PCT/CN2019/086064

§ 371 Date: Dec. 18, 2019

(30) Foreign Application Priority Data
Jan. 25, 2019 (CN) 201910071650.8

(51) Int. Cl. G06N 10/00; G06N 20/00; G06N 5/04

(52) U.S. Cl. CPC G06N 10/00; H03K 19/195; G06N 5/04; G06N 20/00

(57) ABSTRACT

The present disclosure provides a method and an apparatus for constructing a quantum machine learning framework, a quantum computer and a computer storage medium. The method includes: obtaining a Hamiltonian corresponding to a set problem and a number of quantum bits required by the set problem, obtaining target bits according to the number of the quantum bits, obtaining a variational quantum circuit of the set problem according to the target bits and the Hamiltonian, determining a quantum bit to be measured from the target bit, constructing a quantum-operation node class that provides an expectation-value solving interface and a gradient solving interface according to the quantum bit to be measured, the Hamiltonian and the variational quantum circuit, and calling the gradient solving interface and the expectation-value solving interface provided on the quantum-operation node class inserted into a preset machine learning framework to solve the set problem, so as to construct the quantum machine learning framework. With the above method, the quantum machine learning framework may be applied to the quantum computer, so that hybrid programming of a neural network and quantum computing may be realized, and the quantum computer may perform machine learning.

### CROSS-REFERENCE TO RELATED APPLICATION

The present application claims a priority to Chinese Patent Application No. 2019100716508, filed with the China National Intellectual Property Administration on Jan. 25, 2019, and titled “METHOD AND APPARATUS FOR CONSTRUCTING QUANTUM MACHINE LEARNING FRAMEWORK, AND QUANTUM COMPUTER”, the disclosure of which is incorporated herein by reference.

### FIELD

The present disclosure relates to the field of quantum technologies, and more particularly, to a method and an apparatus for constructing a quantum machine learning framework, a quantum computer and a computer storage medium.

### BACKGROUND

Compared with common computers, quantum computers can process mathematical problems more efficiently, for example, the quantum computers reduce the duration for decoding RSA keys from hundreds of years to hours. Therefore, the quantum computers are a key technology under study. In addition, with technological breakthroughs acquired in the field of machine learning in recent years, more and more large-scale commercial corporations increase their investments and researches on artificial intelligence applications. To advance the development progress, various corporations have developed different machine learning frameworks to make the best of computing resources of physical computer clusters.

The inventors find that, in conventional machine learning frameworks, usually a multilayer neural network is trained, so that gradients and expectation values are used to optimize each input parameter. However, the conventional machine learning frameworks can only be applied to the common computers and cannot be applied to the quantum computers; hence, hybrid programming of the neural network and the quantum computer cannot be realized, and further the machine learning cannot be realized with the quantum computers. Consequently, it is an urgent technical problem to be solved to provide a quantum machine learning framework that may be applied to the quantum computers.

### SUMMARY

In this regard, objectives of the present disclosure include, for example, providing a method and an apparatus for constructing a quantum machine learning framework, a quantum computer and a computer storage medium, so as to efficiently solve the above technical problem.

To realize at least one of the above objectives, embodiments of the present disclosure adopt the following technical solutions.

A method for constructing a quantum machine learning framework, including:

with respect to a set problem, obtaining a Hamiltonian corresponding to the set problem;

obtaining a number of quantum bits required by the set problem, and obtaining target bits according to the number of the quantum bits;

obtaining a variational quantum circuit of the set problem according to the target bits and the Hamiltonian;

determining a quantum bit to be measured from the target bits, and constructing a quantum-operation node class that provides an expectation-value solving interface and a gradient solving interface according to the quantum bit to be measured, the Hamiltonian and the variational quantum circuit; and

with respect to the set problem, calling the gradient solving interface and the expectation-value solving interface provided on the quantum-operation node class inserted into a preset machine learning framework to solve the set problem, so as to construct the quantum machine learning framework.

Alternatively, in the above-mentioned method for constructing the quantum machine learning framework, obtaining the Hamiltonian corresponding to the set problem includes:

decoding-encoding the set problem to a ground state of the Hamiltonian of the set problem, so as to convert the set problem into solving the ground state of the Hamiltonian of the set problem.

Alternatively, in the above-mentioned method for constructing the quantum machine learning framework, the Hamiltonian is obtained by linear superposition of at least one Hamiltonian component; and obtaining the number of the quantum bits required by the set problem includes:

counting the number of the quantum bits required according to a serial number of the quantum bit at the bottom right corner of a quantum operator in each Hamiltonian component.

Alternatively, in the above-mentioned method for constructing the quantum machine learning framework, obtaining the variational quantum circuit of the set problem according to the target bits and the Hamiltonian includes:

obtaining a quantum operator corresponding to the Hamiltonian as a target operator; and

constructing the variational quantum circuit according to the target bits, the target operator and a preset quantum gate converter, in which upon receiving the target operator, the preset quantum gate converter obtains a matrix corresponding to the target operator, converts the matrix into a group of preset basic vectors, and obtains a plurality of quantum gates corresponding to the group of preset basic vectors, so as to convert the target operator into the variational quantum circuit.

Alternatively, in the above-mentioned method for constructing the quantum machine learning framework, the quantum gate is a quantum gate containing a fixed parameter or a quantum gate containing a variable parameter, and the variational quantum circuit includes the quantum gate containing the fixed parameter and at least one quantum gate containing the variable parameter.

Alternatively, in the above-mentioned method for constructing the quantum machine learning framework, constructing the quantum-operation node class that provides the expectation-value solving interface and the gradient solving interface according to the quantum bit to be measured, the Hamiltonian and the variational quantum circuit includes:

generating a quantum program interface according to the quantum bit to be measured, the Hamiltonian and the variational quantum circuit, in which a quantum program provided by the quantum program interface includes a measurement operation instruction aiming at the quantum bit to be measured;

generating a quantum program execution interface according to a quantum-state distribution probability obtained from the quantum program being loaded and operated to perform quantum computing until the measurement operation instruction in the quantum program is executed; and

generating an interface for obtaining a target computed value of the quantum-operation node class according to the quantum-state distribution probability, in which the target computed value is a gradient value or an expectation value.

Alternatively, in the above-mentioned method for constructing the quantum machine learning framework, the Hamiltonian is a linear combination of a plurality of Hamiltonian components, each of the Hamiltonian components having a ratio coefficient, and when the target computed value is a total expectation value;

with respect to the set problem, calling the expectation-value solving interface provided on the quantum-operation node class inserted into the preset machine learning framework to solve the set problem includes:

traversing each of the Hamiltonian components in the Hamiltonian;

for a current Hamiltonian component traversed, calling the quantum program interface to construct a first target program, assigning a value to the first target program, calling the quantum program execution interface to obtain the quantum-state distribution probability, and taking the quantum-state distribution probability obtained as a current expectation value;

updating the total expectation value according to the current expectation value and the ratio coefficient of the Hamiltonian corresponding to the current expectation value; and

obtaining an updated total expectation value until all the Hamiltonian components are traversed.

Alternatively, in the above-mentioned method for constructing the quantum machine learning framework, the Hamiltonian is a linear combination of a plurality of Hamiltonian components, each of the Hamiltonian components having a ratio coefficient, and when the target computed value is a total gradient value;

with respect to the set problem, calling the gradient solving interface provided on the quantum-operation node class inserted into the preset machine learning framework to solve the set problem includes:

traversing the Hamiltonian components in the Hamiltonian;

for a current Hamiltonian component traversed, determining variational quantum gates containing a specific gradient solving parameter in the variational quantum circuit, and traversing the variational quantum gates;

for a current variational quantum gate traversed, calling the quantum program interface to generate the quantum program, and obtaining a current gradient value corresponding to the current variational quantum gate according to the quantum program;

updating a gradient value corresponding to the current Hamiltonian component according to the current gradient value of the current variational quantum gate until each variational quantum gate is traversed, and taking the gradient value corresponding to the current Hamiltonian component as a current first gradient value; and

updating the total gradient value according to the first gradient value and the ratio coefficient of the Hamiltonian component corresponding to the first gradient value.

Alternatively, in the above-mentioned method for constructing the quantum machine learning framework, for the current variational quantum gate traversed, calling the quantum program interface to generate the quantum program, and obtaining the current gradient value corresponding to the current variational quantum gate according to the quantum program include:

calling the quantum program interface according to a rule that a parameter of the current variational quantum gate increases in a forward direction and decreases in a backward direction to construct two second target programs, respectively, assigning a value to each of the two second target programs, calling the quantum program execution interface to obtain each quantum-state distribution probability, and processing the each quantum-state distribution probability obtained, so as to obtain the current gradient value corresponding to the current variational quantum gate.

Alternatively, in the above-mentioned method for constructing the quantum machine learning framework, calling the quantum program interface according to the rule that the parameter of the current variational quantum gate increases in the forward direction and decreases in the backward direction to construct the two second target programs, respectively, includes:

for the current variational quantum gate traversed, according to the rule that the parameter of the current variational quantum gate increases in the forward direction, calling the quantum program interface to construct one of the second target programs according to the quantum bit to be measured, the Hamiltonian and the variational quantum circuit obtained by adding π/2 to the specific gradient solving parameter of the current variational quantum gate; and

for the current variational quantum gate traversed, according to the rule that the parameter of the current variational quantum gate decreases in the backward direction, calling the quantum program interface to construct the other one of the second target programs according to the quantum bit to be measured, the Hamiltonian and the variational quantum circuit obtained by subtracting π/2 from the specific gradient solving parameter of the current variational quantum gate.

The present disclosure further provides an apparatus for constructing a quantum machine learning framework, including:

a Hamiltonian obtaining module, configured to, with respect to a set problem, obtain a Hamiltonian corresponding to the set problem;

a bit obtaining module, configured to obtain a number of quantum bits required by the set problem, and to obtain target bits according to the number of the quantum bits;

a quantum circuit obtaining module, configured to obtain a variational quantum circuit of the set problem according to the target bits and the Hamiltonian;

a quantum-operation node class obtaining module, configured to determine a quantum bit to be measured from the target bits, and to construct a quantum-operation node class that provides an expectation-value solving interface and a gradient solving interface according to the quantum bit to be measured, the Hamiltonian and the variational quantum circuit; and

a framework construction module, configured to, with respect to the set problem, call the gradient solving interface and the expectation-value solving interface provided on the quantum-operation node class inserted into a preset machine learning framework to solve the set problem, so as to construct the quantum machine learning framework.

Alternatively, the quantum circuit obtaining module is configured to:

obtain a quantum operator corresponding to the Hamiltonian as a target operator; and

construct the variational quantum circuit according to the target bits, the target operator and a preset quantum gate converter, in which upon receiving the target operator, the preset quantum gate converter obtains a matrix corresponding to the target operator, converts the matrix into a group of preset basic vectors, and obtains a plurality of quantum gates corresponding to the group of preset basic vectors, so as to convert the target operator into the variational quantum circuit.

Alternatively, the quantum-operation node class obtaining module is configured to:

generate a quantum program interface according to the quantum bit to be measured, the Hamiltonian and the variational quantum circuit, in which a quantum program provided by the quantum program interface includes a measurement operation instruction aiming at the quantum bit to be measured;

generate a quantum program execution interface according to a quantum-state distribution probability obtained from the quantum program being loaded and operated to perform quantum computing until the measurement operation instruction in the quantum program is executed; and

generate an interface for obtaining a target computed value of the quantum-operation node class according to the quantum-state distribution probability, in which the target computed value is a gradient value or an expectation value.

The present disclosure further provides a quantum computer, including a storage device, a classic processor, a quantum processor, and a program stored in the storage device and operable on the classic processor and the quantum processor, wherein the classic processor runs the program in combination with the quantum processor, to implement:

with respect to a set problem, obtaining a Hamiltonian corresponding to the set problem;

obtaining a number of quantum bits required by the set problem, and obtaining target bits according to the number of the quantum bits;

obtaining a variational quantum circuit of the set problem according to the target bits and the Hamiltonian;

determining a quantum bit to be measured from the target bits, and constructing a quantum-operation node class that provides an expectation-value solving interface and a gradient solving interface according to the quantum bit to be measured and the variational quantum circuit; and

with respect to the set problem, calling the gradient solving interface and the expectation-value solving interface provided on the quantum-operation node class inserted into a preset machine learning framework to solve the set problem, so as to construct the quantum machine learning framework.

The present disclosure further provides a computer storage medium, which stores a program used in the quantum computer as described above.

The method and the apparatus for constructing the quantum machine learning framework, the quantum computer and the computer storage medium according to the present disclosure obtain the Hamiltonian corresponding to the set problem and the number of the quantum bits required by the set problem, obtain the target bits according to the number of the quantum bits, obtain the variational quantum circuit of the set problem according to the target bits and the Hamiltonian, determine the quantum bit to be measured from the target bits, construct the quantum-operation node class that provides the expectation-value solving interface and the gradient solving interface according to the quantum bit to be measured, the Hamiltonian and the variational quantum circuit, and with respect to the set problem, call the gradient solving interface and the expectation-value solving interface provided on the quantum-operation node class inserted into the preset machine learning framework to solve the set problem, so as to construct the quantum machine learning framework, so that the quantum machine learning framework may be applied to quantum computers. In the above process, as the quantum-operation node class has the expectation-value solving interface, the quantum-operation node class may be suitable for a forward propagation algorithm like a classic neural network node; and as the quantum-operation node class has the gradient solving interface, the quantum-operation node class may be suitable for a back propagation algorithm like the classic neural network node, so that hybrid programming of a neural network and quantum computing may be realized, and the quantum computer may perform machine learning.

In order to make the above-mentioned objectives, features and advantages of the present disclosure more apparent and comprehensible, preferred embodiments are described below in combination with the accompanying drawings.

### BRIEF DESCRIPTION OF THE DRAWINGS

FIG. 1 is a block diagram of a connection of a quantum computer according to an embodiment of the present disclosure.

FIG. 2 is a flowchart of a method for constructing a quantum machine learning framework according to an embodiment of the present disclosure.

FIG. 3 is a flowchart of block S130 in FIG. 2.

FIG. 4A illustrates a node of a variational quantum circuit.

FIG. 4B illustrates a data node of a variational quantum gate.

FIG. 5 is a flowchart of block S140 in FIG. 2.

FIG. 6 is a flowchart of block S150 in FIG. 2.

FIG. 7 is another flowchart of block S150 in FIG. 2.

FIG. 8 is a schematic diagram of a conventional expression structure.

FIG. 9 is a schematic diagram of a structure of a quantum-operation node class according to the present disclosure.

FIG. 10 is a block diagram of a connection of an apparatus for constructing a quantum machine learning framework according to an embodiment of the present disclosure.

### REFERENCE NUMERALS OF THE ACCOMPANYING DRAWING

10—quantum computer; 12—storage device; 14—classic processor; 16—quantum processor; 100—apparatus for constructing a quantum machine learning framework; 110—Hamiltonian obtaining module; 120—bit obtaining module; 130—quantum circuit obtaining module; 140—quantum-operation node class obtaining module; 150—framework construction module.

### DETAILED DESCRIPTION

In order to make the objectives, technical solutions and advantages of the embodiments of the present disclosure clearer, reference will be made clearly and completely to technical solutions in the embodiments of the present disclosure with accompanying drawings. Obviously, the embodiments described here are only part of the embodiments of the present disclosure and are not all embodiments of the present disclosure. Components of the embodiments according to the present disclosure, which are generally described and illustrated in the drawings herein, may be arranged and designed in a variety of configurations.

Therefore, the following detailed description of the embodiments according to the present disclosure provided in the drawings is not intended to limit the scope of the present disclosure, but merely represents selected embodiments of the present disclosure. Based on the embodiments according to the present disclosure, all other embodiments obtained by those skilled in the art without inventive work shall fall within the protection scope of the present disclosure.

It should be noted that similar reference numerals and letters indicate similar items in the following drawings, so once an item is defined in one figure, it is unnecessary to further define and explain the item in subsequent figures.

In the present disclosure, unless specified or limited otherwise, the terms “arranged” “connected” and “coupled” are understood broadly, such as fixed, detachable mountings, connections and couplings or integrated, and can be mechanical or electrical mountings, connections and couplings, and also can be direct and via media indirect mountings, connections, and couplings, and further can be inner mountings, connections and couplings of two components or interaction relations between two components, which can be understood by those skilled in the art according to the detail embodiment of the present disclosure.

Referring to FIG. 1, a quantum computer 10 provided in the present disclosure is a physical device that performs high-speed mathematical and logical operations as well as stores and processes quantum information in accordance with the laws of quantum mechanics. The quantum computer 10 includes: a storage device 12, a classic processor 14 and a quantum processor 16. It should be noted that the classic processor 14 is configured to run a program stored on the storage device 12 to generate a quantum program and to call a quantum program execution interface. The quantum program execution interface is connected to the quantum processor 16. The quantum processor 16 includes a quantum program compilation-control module and a quantum chip, in which the quantum program compilation-control module is configured to perform quantum program compilation and conversion, and to convert the compiled quantum program into an analog signal required to control the operation of the quantum chip. The quantum chip changes a quantum state of a quantum bit by running the analog signal, and the quantum program compilation-control module measures the quantum state of the quantum bit. Specifically, the quantum program compilation-control module obtains the analog signal indicating the quantum state of the quantum bit, converts the analog signal into a digital signal, and sends the digital signal to the classic processor 14. After that, the classic processor 14 processes the digital signal and obtains a quantum-state distribution probability.

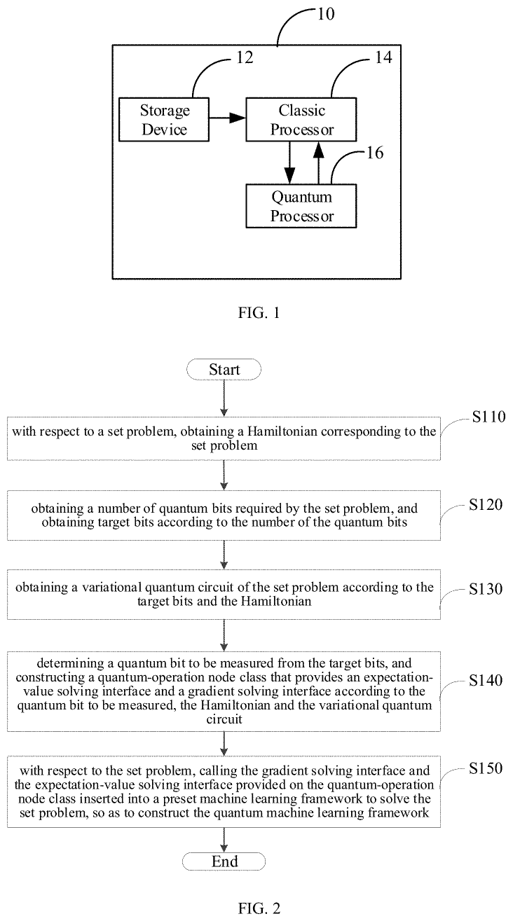

Referring to FIG. 2, the present disclosure provides a method for constructing a quantum machine learning framework. The method for constructing the quantum machine learning framework may be applied to the quantum computer 10. The method for constructing the quantum machine learning framework executes blocks S110 to S150 when applied to the quantum computer 10.

At block S110: with respect to a set problem, a Hamiltonian corresponding to the set problem is obtained.

In detail, a specific manner of obtaining the Hamiltonian corresponding to the set problem may include decoding-encoding the set problem to a ground state of the Hamiltonian of the set problem, so as to convert the set problem into solving the ground state of the Hamiltonian of the set problem.

In this embodiment, the Hamiltonian may be represented by an expansion of a Pauli operator. It is known that the Pauli operator is at least one of or a combination of Pauli-X gate, Pauli-Y gate and Pauli-Z gate.

Exemplarily, H=0.1X₀+0.2Y₁Z₂+1.2X₃Y₄Z₀; where H is a Hamiltonian, X, Y and Z are respectively Pauli-X gate, Pauli-Y gate, and Pauli-Z gate and are collectively referred to as the quantum operator, and a digital number at the bottom right corner of the quantum operator is a serial number of the quantum bit, the quantum operator and the serial number of the quantum bit as a whole indicating that the quantum operator acts on the quantum bit. For example, X₀ means that Pauli-X gate acts on a quantum bit numbered 0, Y₁ means that Pauli-Y gate acts on a quantum bit numbered 1, Z₂ means that Pauli-Z gate acts on a quantum bit numbered 2, and so on.

The Hamiltonian H is a linear superposition of at least one Hamiltonian component. In the example of H=0.1X₀+0.2Y₁Z₂+1.2X₃Y₄Z₀, X₀ is a Hamiltonian component, Y₁Z₂ as a whole is a Hamiltonian component, and X₃Y₄Z₀ as a whole is a Hamiltonian component. The coefficient before each Hamiltonian component is a ratio coefficient corresponding to the Hamiltonian component, that is, the Hamiltonian includes several Hamiltonian components, and each Hamiltonian component has a corresponding ratio coefficient.

When a Hamiltonian includes several quantum operators acting on the same serial number of the quantum bit and the quantum operators correspond to Pauli operators, the quantum operators corresponding to the same serial number of the quantum bit may be combined on a basis that: the quantum operators and the Pauli operators have a correspondence relationship, the Pauli operators include one of or a combination of Pauli-X gate, Pauli-Y gate and Pauli-Z gate while Pauli-X gate, Pauli-Y gate and Pauli-Z gate are all single quantum gates, which satisfy the combination rule, so the quantum operators may be combined by a direct product multiplication of unitary matrixes corresponding to the single quantum gates. Therefore, according to the combination rule of the single quantum gates, it is possible to combine several quantum operators corresponding to the same serial number of the quantum bit contained in one Hamiltonian, thereby simplifying the quantum program.

Exemplarily, X₁Y₁=j*Z₁. It may be understood that X, Y and Z in X₁Y₁=j*Z₁ each identifies the single quantum gate, the subscript 1 identifies the serial number of the quantum bit, and j is a transformation complex number obtained when the multiplication is performed on the unitary matrixes corresponding to the single quantum gates X and Y to obtain a unitary matrix corresponding to the single quantum gate Z.

It should be noted that although the Pauli operator is used as a basis for calculating the Hamiltonian in this embodiment, it is feasible to switch to another computing base. In addition to the Pauli operator, similar bases include the Fermion operator. Apart from being represented by an operator, the Hamiltonian may also be represented by a matrix. Similar representations may be represented by converting the computing base into the Pauli operator, so as to enable the converted Hamiltonian of the Pauli operator is completely (for the finite-dimensional Hilbert space) or infinitely (for the infinite-dimensional Hilbert space) resemble the original physical system.

Take the chemical simulation problem as an example. The problem Hamiltonian is a Hamiltonian represented by the Fermion operator and may be constructed by atoms in a molecule, an electronic structure and a computer. The Hamiltonian of the Fermion operator may be further converted into the Hamiltonian represented by the Pauli operator by Jordan-Wigner transformation.

Take the MAX-CUT problem as another example. Each node in the MAX-CUT problem is encoded as a bit, and the problem Hamiltonian is H=Σ_{i,j∈E}zᵢ⊗zⱼ, where E represents each side in the MAX-CUT problem, Z represents Pauli-Z operator, and a binary representation corresponding to the ground state of the Hamiltonian is exactly equal to an optimal solution configuration for the MAX-CUT problem.

At block S120, a number of quantum bits required by the set problem is obtained, and target bits are obtained according to the number of the quantum bits.

It should be noted that the number of the quantum bits required by the set problem may be counted according to the serial number of the quantum bit at the bottom right corner of the quantum operator in each Hamiltonian component. The corresponding quantum bits may be requested from the quantum processor 16, and the corresponding classic bits may be requested from the classic processor 14, according to the required number of the quantum bits, in which the classic bits and the quantum bits have a one-to-one mapping correspondence relationship and may be recorded as the target bits. The former (the classic bit) is used for quantum program programming. As in this embodiment, the classic bit is used as the target bit. The latter (the quantum bit) is used to perform quantum computing according to the quantum program. The quantum bit is a basic execution unit of the quantum computer. The classic bit and the quantum bit are in a one-to-one mapping correspondence relationship. Therefore, the quantum program generated in a classical computer may be loaded on the quantum processor 16 for quantum computing.

It should be noted that in order to ensure that the quantum program constructed may be executed on the quantum computer 10 (such as the quantum processor 16 in the quantum computer 10), the number of the quantum bits required by the set problem may be determined first, and then the target bits may be requested from the quantum computer 10, and it may be determined whether the quantum bits are successfully requested or not. When the quantum bits are successfully requested, the quantum program may be constructed according to the classic bits, and then the quantum program is loaded on the quantum computer 10 to perform quantum computing, and the quantum computer 10 returns a running result. When the quantum bits are not successfully requested, an error message is returned directly and the process ends.

At block S130, a variational quantum circuit of the set problem is obtained according to the target bits and the Hamiltonian.

Constructing the variational quantum circuit for the set problem according to the target bits and the Hamiltonian refers to transforming the quantum operator corresponding to the Hamiltonian into a variational quantum gate, and the variational quantum gate forms the variational quantum circuit together with the target bits.

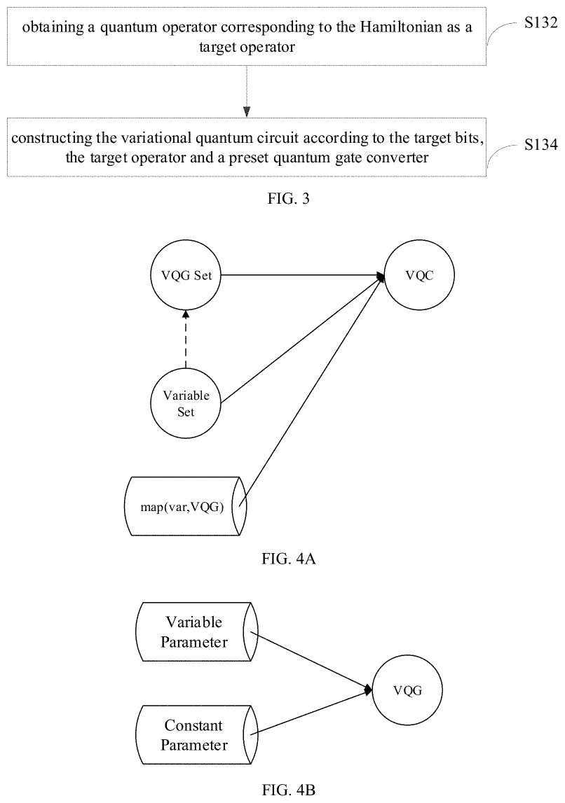

Referring to FIG. 3, the block S130 may include the followings.

At block S132, a quantum operator corresponding to the Hamiltonian is obtained as a target operator.

At block S134, the variational quantum circuit is constructed according to the target bits, the target operator and a preset quantum gate converter, in which upon receiving the target operator, the preset quantum gate converter obtains a matrix corresponding to the target operator, converts the matrix into a group of preset basic vectors, and obtains a plurality of quantum gates corresponding to the group of preset basic vectors, so as to convert the target operator into the variational quantum circuit. The quantum gate includes a variational quantum gate, which is a gate containing a variable parameter or a gate containing a fixed parameter. The variational quantum circuit (VQC) is formed by combining the variational quantum gates with the target bits.

To describe the VQC more efficiently, the embodiment provides a VQC node as shown in FIG. 4a. The VQC node internally maintains a set of VQG nodes (a VQG set), a set of variables (a variable set), and a set of mapping relationships map (var, VQG); in which the variables have initial parameter values, map (var, VQG) represents a mapping relationship between the variables var and the VQG nodes, and the same variable may correspond to different VQG nodes.

Optionally, in specific operation, considering that the quantum gate includes the quantum gate containing the variable parameter or the quantum gate containing the fixed parameter, and both the quantum gate containing the variable parameter and the quantum gate containing the fixed parameter include a quantum-gate-type identifier and a parameter, in order to effectively describe the quantum gate in the classical computer, the embodiment provides a data node of the variational quantum gate as shown in FIG. 4b, and the data node of the variational quantum gate (VQG) internally maintains a set of variable parameters and a set of constant parameters. Only one set of parameters may be assigned values when the VQG node is constructed. When a set of constant parameters is included, fixed quantum gates including constant parameters (i.e., the quantum gates containing the fixed parameters) may be generated by the VQG; and when the variable parameters are included, parameter values may be dynamically modified, and corresponding quantum gates (i.e., the quantum gates containing the variable parameters) may be generated. It should be noted that the variational quantum circuit constructed by calling the variational quantum gates of the data structure needs to include the quantum gate containing the fixed parameter and at least one quantum gate containing the variable parameter. The specific number of the quantum gates containing the fixed parameters and the number of the quantum gates containing the variational parameters need to be determined according to specific conditions.

At block S140, a quantum bit to be measured is determined from the target bits, and a quantum-operation node class that provides an expectation-value solving interface and a gradient solving interface is constructed according to the quantum bit to be measured, the Hamiltonian and the variational quantum circuit.

Referring to FIG. 5, in this embodiment, block S140 may include blocks S142 to S146.

At block S142, a quantum program interface is generated according to the quantum bit to be measured, the Hamiltonian and the variational quantum circuit, in which a quantum program provided by the quantum program interface includes a measurement operation instruction aiming at the quantum bit to be measured.

At block S144, a quantum program execution interface is generated according to a quantum-state distribution probability obtained from the quantum program being loaded and operated to perform quantum computing until the measurement operation instruction in the quantum program is executed.

It should be noted that the quantum program being loaded and operated to perform the quantum computing until the measurement operation instruction in the quantum program is executed is performed on the quantum computer 10. When the quantum computer 10 executes the quantum program, the quantum program may be executed for several times according to preset execution times of the quantum program. A measurement value is obtained each time the quantum program is executed to the measurement operation instruction, and then the measurement values obtained after the several times are counted to obtain the corresponding quantum-state distribution probability.

At block S146, an interface for obtaining a target computed value of the quantum-operation node class is generated according to the quantum-state distribution probability, in which the target computed value is a gradient value or an expectation value.

At block S150, with respect to the set problem, the gradient solving interface and the expectation-value solving interface provided on the quantum-operation node class inserted into a preset machine learning framework are called to solve the set problem, so as to construct the quantum machine learning framework.

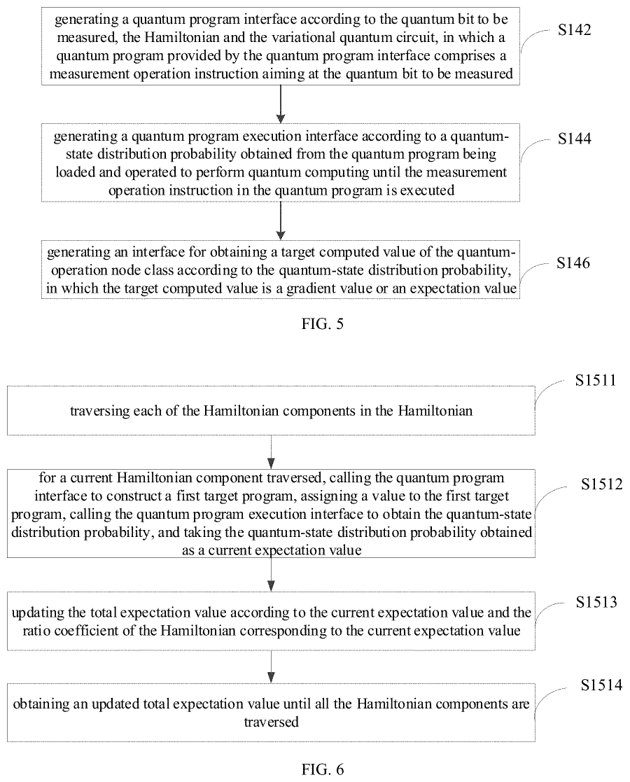

Alternatively, the Hamiltonian is a linear combination of a plurality of Hamiltonian components, each of the Hamiltonian components having a ratio coefficient. When the target computed value is a total expectation value, referring to FIG. 6, the step of, with respect to the set problem, the gradient solving interface and the expectation-value solving interface provided on the quantum-operation node class inserted into the preset machine learning framework are called to solve the set problem, so as to construct the quantum machine learning framework at block S150 may include the followings.

At block S1511, each of the Hamiltonian components in the Hamiltonian is traversed.

At block S1512, for a current Hamiltonian component traversed, the quantum program interface is called to construct a first target program, a value is assigned to the first target program, and the quantum program execution interface is called to obtain the quantum-state distribution probability, and the quantum-state distribution probability obtained is taken as a current expectation value.

At block S1513, the total expectation value is updated according to the current expectation value and the ratio coefficient of the Hamiltonian corresponding to the current expectation value.

At block S1514, an updated total expectation value is obtained until all the Hamiltonian components are traversed.

The total expectation value may be updated by the following formula: the total expectation value=the current total expectation value+the ratio coefficient corresponding to the current Hamilton*the current expectation value, an initial value of the total expectation value being 0.

For example, a quantum state S may be prepared by a certain sequence of operations (e.g., a quantum circuit generated with the variational quantum circuit after parameters are determined in this embodiment), so as to solve the expectation value of the quantum state for the Hamiltonian. An initial value of the quantum state S may be preset.

In an alternative implementation, the Hamiltonian is transformed to a Hamiltonian represented by the Pauli operator in advance before the process is performed. Each of the components, i.e., parts that are connected by plus signs, of the Hamiltonian is found. For example: H=0.5*X₁X₂+0.2*Z₁Z₂+(−1)Y₀, where X₁X₂ indicates that there is a direct product relationship between X₁ and X₂, Z₁Z₂ also indicates that there is a direct product relationship between Z₁ and Z₂, and a direct product symbol ⊗ is usually omitted. It should be noted that the direct product relationship refers to the direct product between the unitary matrixes corresponding to quantum gates. The direct product operation of the matrixes belongs to common knowledge and will not be described herein. In this case, the Hamiltonian components are 0.5*X₁X₂, 0.2*Z₁Z₂ and −1*Y₀. Due to the linear nature of the operator, an expectation of the quantum state S on the Hamiltonian is a sum of expectations of the quantum state S on each component.

In principle, for one component, it is possible to have each subscript appear only once. If in a case where a subscript appears more than once, the case may be simply developed into a case where the subscript appears only once. For example, X₁Y₁=j*Z₁, where j is the transformation complex number obtained when the multiplication is performed on the unitary matrixes corresponding to the single quantum gates X and Y to obtain the unitary matrix corresponding to the single quantum gate Z. This simplification may be done at any time before the process is performed. For each subscript occurs in the term, the quantum gate operation corresponding to the quantum operator is again applied to the bit as appropriate.

After that, the quantum bit corresponding to the subscript appearing in the item is measured to obtain a measurement value, which is a binary string, and then the expectation value of the term is determined according to the binary string and the ratio coefficient of the Hamiltonian of the term. In detail, the number of occurrences n of 1 in the binary string is counted, a sub-coefficient of the ratio coefficient of the Hamiltonian of the term is determined according to n, and then the expectation value of the term is obtained by multiplying the sub-coefficient by the ratio coefficient corresponding to the Hamiltonian of the term, in which the sub-coefficient is equal to the n^{th} power of (−1). When the number of occurrences of 1 in the binary string is an even number, the sub-coefficient is equal to 1; and when the number of occurrences of 1 in the binary string is an odd number, the sub-coefficient is equal to −1.

Illustratively, when the binary string is 0101000, the expectation value of the term is: 1; and when the binary string is 0101001, the expectation value of the term is: −1.

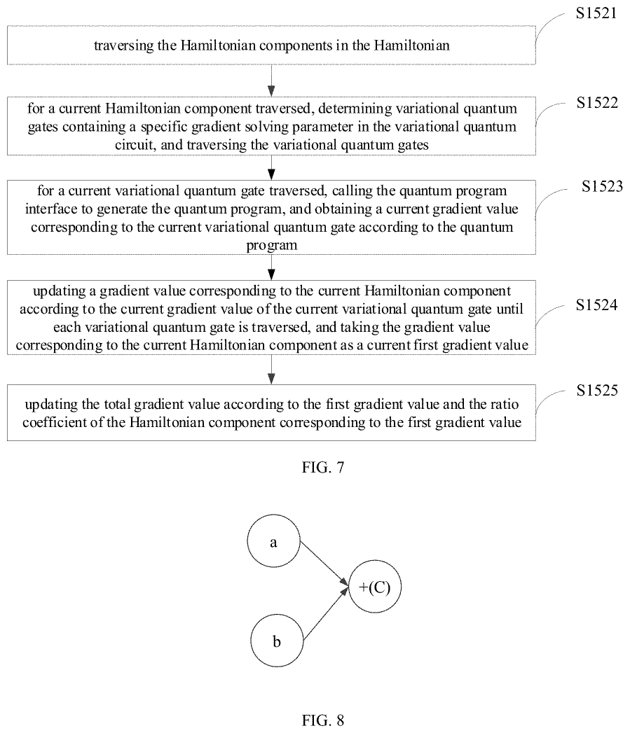

Referring to FIG. 7, in this embodiment, when the target computed value is a total gradient value, the step of, with respect to the set problem, calling the gradient solving interface provided on the quantum-operation node class inserted into the preset machine learning framework to solve the set problem at block S150 may include the followings.

At block S1521, the Hamiltonian components in the Hamiltonian are traversed.

At block S1522, for a current Hamiltonian component traversed, variational quantum gates containing a specific gradient solving parameter in the variational quantum circuit are determined, and the variational quantum gates are traversed.

At block S1523, for a current variational quantum gate traversed, the quantum program interface is called to generate the quantum program, and a current gradient value corresponding to the current variational quantum gate is obtained according to the quantum program.

At block S1524, a gradient value corresponding to the current Hamiltonian component is updated according to the current gradient value of the current variational quantum gate until each variational quantum gate is traversed, and the gradient value corresponding to the current Hamiltonian component is taken as a current first gradient value.

At block S1525, the total gradient value is updated according to the first gradient value and the ratio coefficient of the Hamiltonian component corresponding to the first gradient value.

Alternatively, the step that, for the current variational quantum gate traversed, the quantum program interface is called to generate the quantum program, and the current gradient value corresponding to the current variational quantum gate is obtained according to the quantum program at block S1523 may include the followings.

The quantum program interface is called according to a rule that a parameter of the current variational quantum gate increases in a forward direction and decreases in a backward direction to construct two second target programs, respectively, a value is assigned to each of the two second target programs, the quantum program execution interface is called to obtain each quantum-state distribution probability, and the each quantum-state distribution probability obtained is processed, so as to obtain the current gradient value corresponding to the current variational quantum gate.

It should be noted that the process that the quantum program interface is called according to the rule that the parameter of the current variational quantum gate increases in the forward direction and decreases in the backward direction, respectively, to construct the two second target programs is performed in the classic processor 14 in the quantum computer 10. The two (the two second target programs) may be constructed simultaneously, or one after another. It should be emphasized that values of the specific gradient solving parameters used in the construction are consistent. When executed, the two second target programs may be executed simultaneously by a parallel quantum computer or sequentially by a serial quantum computer.

It may be understood that the parameter increasing in the forward direction and decreasing in the backward direction refer to a change rule of the value of the parameter. Take the parameter being an angle as an example. In a plane rectangular coordinate system, if the horizontal axis X represents an angle parameter, then the angle of the parameter increases when the angle parameter extends along the forward direction of the X axis, and the angle of the parameter decreases when extends along the backward direction of the X axis.

In an alternative implementation, calling the quantum program interface according to the rule that the parameter of the current variational quantum gate increases in the forward direction and decreases in the backward direction to construct the two second target programs, respectively, includes: for the current variational quantum gate traversed, according to the rule that the parameter of the current variational quantum gate increases in the forward direction, calling the quantum program interface to construct one of the second target programs according to the quantum bit to be measured, the Hamiltonian and the variational quantum circuit obtained by adding π/2 to the specific gradient solving parameter of the current variational quantum gate; and for the current variational quantum gate traversed, according to the rule that the parameter of the current variational quantum gate decreases in the backward direction, calling the quantum program interface to construct the other one of the second target programs according to the quantum bit to be measured, the Hamiltonian and the variational quantum circuit obtained by subtracting π/2 from the specific gradient solving parameter of the current variational quantum gate.

By adopting the above blocks, the quantum-operation node class may be verified and implemented. The evaluation processing of the node may be implemented by a forward propagation algorithm, and the gradient solving processing may be implemented by a back propagation algorithm, thereby providing a basis for the quantum-operation node class to be inserted into a preset classic machine learning framework and constructing the quantum machine learning framework.

By adopting the above method, the purpose of constructing the quantum machine learning framework in combination with a preset machine learning framework may be achieved, in which the quantum machine learning framework may be applied to the quantum computer 10. In this process, since the quantum-operation node class has the expectation-value solving interface, the quantum-operation node class may be applied to the forward propagation algorithm like a classic neural network node; moreover, since the quantum-operation node class has the gradient solving interface, the quantum-operation node class may be applied to the back propagation algorithm like the classic neural network node, so that the hybrid programming of the neural network and the quantum computing may be realized, and the quantum computer 10 may perform machine learning.

It should be noted that in a conventional machine learning framework, gradient descent will be used to optimize various input parameters in training the multilayer neural network. In the implementation of the underlying algorithm code, each input parameter and an operator that operates the each input parameter are usually defined as a node variable. For example, when calculating an expression such as “a+b”, referring to FIG. 8, each of “a”, “b” and “+” may be considered as one node (the expression as a whole is taken as another node c, “c=a+b”), a circle icon represents a node variable, and an arrow direction represents a relationship between the nodes. As shown in the figure above, both the node “a” and the node “b” point to the node “+”, indicating that the node “a” and the node “b” are children nodes of the node “+”; and the node “+” is the parent node of the node “a” and the node “b”. The two children nodes may be operated by the node “+” (or a single node variable may also be operated by other operations). When values of the nodes “a” and “b” are determined, since the nodes “a” and “b” are children nodes of the node “+” (the expression “c”), it is easy to solve the value of the variable “+” (the expression “c”). In turn, one may calculate a derivative of the node “a”,

$${a}^{′} = \frac{\partial c}{\partial a}$$

and a derivative of the node “b”,

$${b}^{′} = \frac{\partial c}{\partial b}$$

through the node “+” (the expression “c”). It may be understood that when there is a subgraph of a complex expression, a partial derivative of the node “+” (the expression “c”) for the node “a” and the node “b” may be obtained by the back propagation algorithm.

The present disclosure adopts the above blocks S110 to S150 to introduce the quantum computing into the conventional machine learning framework and introduces quantum operations. Being different from existing operations, such as “+”, “−”, “*”, “/”, “sin” and “log”, that operate directly on one or two variables, the quantum operations operate variables through the variational quantum circuit, and realize quantum computing functions, for example, functions of solving the expectation and the gradient, in combination with the set problem, the quantum bits required by the set problem and the quantum bit to be measured. In detail, referring to FIG. 9, a circular icon represents a variable, a horizontal cylindrical icon represents a parameter, and an arrow direction represents a relationship between nodes or a relationship between a parameter and a node variable. The quantum-operation node class is obtained by combining and constructing the variational quantum circuit, the quantum bit to be measured and the Hamiltonian. For a given variable value in the variational quantum circuit, the expectation and gradient value of the quantum-operation node class may be computed, and thus, the quantum-operation node class may be inserted into a complex neural network.

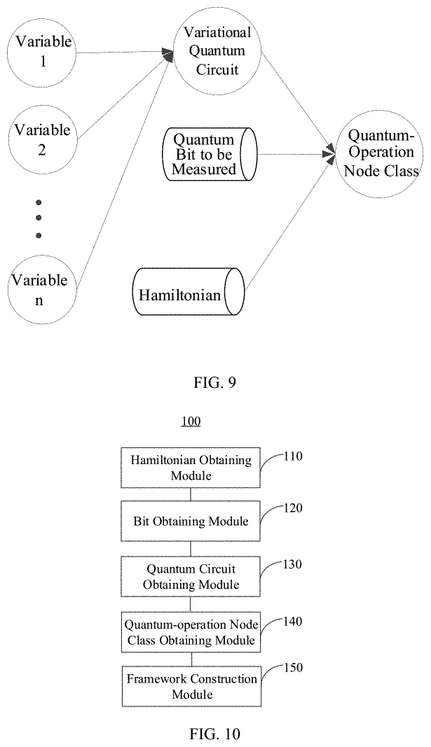

Referring to FIG. 10, according to the above description, the present disclosure further provides an apparatus 100 for constructing a quantum machine learning framework that may be applied to the quantum computer 10. The apparatus 100 for constructing the quantum machine learning framework includes a Hamiltonian obtaining module 110, a bit obtaining module 120, a quantum circuit obtaining module 130, a quantum-operation node class obtaining module 140 and a framework construction module 150.

The Hamiltonian obtaining module 110 is configured to, with respect to the set problem, obtain the Hamiltonian corresponding to the set problem. In this embodiment, the Hamiltonian obtaining module 110 may be configured to implement block S110 in FIG. 2, and thus detailed description of the Hamiltonian obtaining module 110 may be referred to the description of block S110.

The bit obtaining module 120 is configured to obtain the number of the quantum bits required by the set problem, and to obtain the target bits according to the number of the quantum bits. In this embodiment, the bit obtaining module 120 may be configured to implement block S120 in FIG. 2, and thus detailed description of the bit obtaining module 120 may be referred to the description of block S120.

The quantum circuit obtaining module 130 is configured to obtain the variational quantum circuit of the set problem according to the target bits and the Hamiltonian. In this embodiment, the quantum circuit obtaining module 130 may be configured to implement block S130 in FIG. 2, and thus detailed description of the quantum circuit obtaining module 130 may be referred to the description of block S130.

The quantum-operation node class obtaining module 140 is configured to determine the quantum bit to be measured from the target bits, and to construct the quantum-operation node class that provides the expectation-value solving interface and the gradient solving interface according to the quantum bit to be measured, the Hamiltonian and the variational quantum circuit. In this embodiment, the quantum-operation node class obtaining module 140 may be configured to implement block S140 in FIG. 2, and thus detailed description of the quantum-operation node class obtaining module 140 may be referred to the description of block S140.

The framework construction module 150 is configured to, with respect to the set problem, call the gradient solving interface and the expectation-value solving interface provided on the quantum-operation node class inserted into the preset machine learning framework to solve the set problem, so as to construct the quantum machine learning framework. In this embodiment, the framework construction module 150 may be configured to implement block S150 in FIG. 2, and thus detailed description of the framework construction module 150 may be referred to the description of block S150.

Alternatively, the quantum circuit obtaining module 130 is configured to: obtain the quantum operator corresponding to the Hamiltonian as the target operator; and construct the variational quantum circuit according to the target bits, the target operator and the preset quantum gate converter, in which upon receiving the target operator, the preset quantum gate converter obtains the matrix corresponding to the target operator, converts the matrix into the group of preset basic vectors, and obtains the plurality of quantum gates corresponding to the group of preset basic vectors, so as to convert the target operator into the variational quantum circuit.

Alternatively, the quantum-operation node class obtaining module 140 is configured to: generate the quantum program interface according to the quantum bit to be measured, the Hamiltonian and the variational quantum circuit, in which the quantum program provided by the quantum program interface includes the measurement operation instruction aiming at the quantum bit to be measured; generate the quantum program execution interface according to the quantum-state distribution probability obtained from the quantum program being loaded and operated to perform the quantum computing until the measurement operation instruction in the quantum program is executed; and generate the interface for obtaining the target computed value of the quantum-operation node class according to the quantum-state distribution probability, in which the target computed value is the gradient value or the expectation value.

In addition, the present disclosure further provides a computer storage medium, which stores the program used by the quantum computer 10.

In summary, the present disclosure provides the method and the apparatus for constructing the quantum machine learning framework, the quantum computer 10 and the computer storage medium. The method includes: obtaining the Hamiltonian corresponding to the set problem and the number of the quantum bits required by the set problem, obtaining the target bits according to the number of the quantum bits, obtaining the variational quantum circuit of the set problem according to the target bits and the Hamiltonian, determining the quantum bit to be measured from the target bits, constructing the quantum-operation node class that provides the expectation-value solving interface and the gradient solving interface according to the quantum bit to be measured, the Hamiltonian and the variational quantum circuit, and with respect to the set problem, calling the gradient solving interface and the expectation-value solving interface provided on the quantum-operation node class inserted into the preset machine learning framework to solve the set problem, so as to construct the quantum machine learning framework. In the above process, as the quantum-operation node class has the expectation-value solving interface, the quantum-operation node class may be suitable for a forward propagation algorithm like a classic neural network node; and as the quantum-operation node class has the gradient solving interface, the quantum-operation node class may be suitable for a back propagation algorithm like the classic neural network node. Consequently, according to the above method, the quantum machine learning framework may be applied to the quantum computer 10, so that the hybrid programming of the neural network and the quantum computing may be realized, and the quantum computer 10 may perform machine learning.

It should be noted that the quantum computer 10 according to the present disclosure includes the storage device 12, the classic processor 14, the quantum processor 16, and the program stored in the storage device 12 and operable on the classic processor 14 and the quantum processor 16. The classic processor 14 runs the program in combination with the quantum processor 16, to implement specific blocks in the method for constructing the quantum machine learning framework.

At block S110, with respect to the set problem, the Hamiltonian corresponding to the set problem is obtained.

At block S120, the number of the quantum bits required by the set problem is obtained, and the target bits is obtained according to the number of the quantum bits.

At block S130, the variational quantum circuit of the set problem is obtained according to the target bits and the Hamiltonian.

At block S140, the quantum bit to be measured is determined from the target bits, and the quantum-operation node class that provides the expectation-value solving interface and the gradient solving interface is constructed according to the quantum bit to be measured, the Hamiltonian and the variational quantum circuit.

At block S150, with respect to the set problem, the gradient solving interface and the expectation-value solving interface provided on the quantum-operation node class inserted into the preset machine learning framework are called to solve the set problem, so as to construct the quantum machine learning framework.

In the several embodiments provided by the embodiments of the present disclosure, it should be understood that the disclosed apparatus and method may also be implemented in other ways. The apparatus and method embodiments described above are merely illustrative. For example, the flowcharts and block diagrams in the accompanying drawings show possible architectures, functions and operations of the apparatus, the method and the computer program product according to various embodiments of the present disclosure. In this regard, each block in the flowchart or block diagram may represent a module, a program segment or a portion of a code, which contain one or more executable instructions for implementing a specified logical function. It should also be noted that in some alternative implementations, functions marked by blocks may also occur in an order differing from that marked in the drawings. For example, two consecutive blocks may actually be executed substantially in parallel, or sometimes be executed in a reverse order, depending on functions involved. It should also be noted that each block in a block diagram and/or a flowchart, and combinations of blocks in the block diagrams and/or flowcharts, may be implemented in a dedicated hardware-based system that performs specified functions or actions, or may be implemented by a combination of dedicated hardware and computer instructions.

In addition, the functional modules in the various embodiments according to the present disclosure may be integrated to form an independent part, or each module may exist separately, or two or more modules may be integrated to form an independent part.

If the functions are implemented in the form of software functional modules and sold or used as independent products, the functions may be stored in a computer readable storage medium. Based on this understanding, the technical solution of the present disclosure essentially, a part that contributes to the prior art or a part of the technical solution may be embodied in the form of a software product. The computer software product is stored in a storage medium, including several instructions used to enable a computer device to perform all or some of the steps of the method described in the embodiments of the present disclosure. It should be noted that in the present disclosure, terms “including”, “comprising” or any other variants thereof are intended to cover non-exclusive inclusions, so that a process, a method, an article or a device including a series of elements includes not only the series of elements, but also other elements not explicitly listed, or elements inherent to such a process, method, article, or device. Without other restrictions, elements defined by the sentence “including a . . . ” do not exclude the existence of other identical elements in the process, method, article, or device that includes the elements.

The above embodiments are merely preferred embodiments of the present disclosure, and are not intended to limit the present disclosure. For those skilled in the art, various modifications and changes may be made to the present disclosure. Any modification, equivalent replacement, or improvement made within the spirit and principle of the present disclosure shall be included in the protection scope of the present disclosure.

### INDUSTRIAL APPLICABILITY

With the technical solution of the present disclosure, the quantum machine learning framework may be applied to the quantum computer, so that the hybrid programming of the neural network and the quantum computing may be realized, and the quantum computer may perform machine learning.

1. A method for constructing a quantum machine learning framework, comprising:
with respect to a set problem, obtaining a Hamiltonian corresponding to the set problem;
obtaining a number of quantum bits required by the set problem, and obtaining target bits according to the number of the quantum bits;
obtaining a variational quantum circuit of the set problem according to the target bits and the Hamiltonian;
determining a quantum bit to be measured from the target bits, and constructing a quantum-operation node class that provides an expectation-value solving interface and a gradient solving interface according to the quantum bit to be measured, the Hamiltonian and the variational quantum circuit; and
with respect to the set problem, calling the gradient solving interface and the expectation-value solving interface provided on the quantum-operation node class inserted into a preset machine learning framework to solve the set problem, so as to construct the quantum machine learning framework.

2. The method for constructing a quantum machine learning framework according to claim 1, wherein obtaining the Hamiltonian corresponding to the set problem comprises:
decoding-encoding the set problem to a ground state of the Hamiltonian of the set problem, so as to convert the set problem into solving the ground state of the Hamiltonian of the set problem.

3. The method for constructing a quantum machine learning framework according to claim 1, wherein the Hamiltonian is obtained by linear superposition of at least one Hamiltonian component; and
obtaining the number of the quantum bits required by the set problem comprises:
counting the number of the quantum bits required according to a serial number of the quantum bit at the bottom right corner of a quantum operator in each Hamiltonian component.

4. The method for constructing a quantum machine learning framework according to claim 1, wherein obtaining the variational quantum circuit of the set problem according to the target bits and the Hamiltonian comprises:
obtaining a quantum operator corresponding to the Hamiltonian as a target operator; and
constructing the variational quantum circuit according to the target bits, the target operator and a preset quantum gate converter, in which upon receiving the target operator, the preset quantum gate converter obtains a matrix corresponding to the target operator, converts the matrix into a group of preset basic vectors, and obtains a plurality of quantum gates corresponding to the group of preset basic vectors, so as to convert the target operator into the variational quantum circuit.

5. The method for constructing a quantum machine learning framework according to claim 4, wherein the quantum gate is a quantum gate containing a fixed parameter or a quantum gate containing a variable parameter, and the variational quantum circuit comprises the quantum gate containing the fixed parameter and at least one quantum gate containing the variable parameter.

6. The method for constructing a quantum machine learning framework according to according to claim 1, wherein constructing the quantum-operation node class that provides the expectation-value solving interface and the gradient solving interface according to the quantum bit to be measured, the Hamiltonian and the variational quantum circuit comprises:
generating a quantum program interface according to the quantum bit to be measured, the Hamiltonian and the variational quantum circuit, in which a quantum program provided by the quantum program interface comprises a measurement operation instruction aiming at the quantum bit to be measured;
generating a quantum program execution interface according to a quantum-state distribution probability obtained from the quantum program being loaded and operated to perform quantum computing until the measurement operation instruction in the quantum program is executed; and
generating an interface for obtaining a target computed value of the quantum-operation node class according to the quantum-state distribution probability, in which the target computed value is a gradient value or an expectation value.

7. The method for constructing a quantum machine learning framework according to claim 6, wherein the Hamiltonian is a linear combination of a plurality of Hamiltonian components, each of the Hamiltonian components having a ratio coefficient, and when the target computed value is a total expectation value;
with respect to the set problem, calling the expectation-value solving interface provided on the quantum-operation node class inserted into the preset machine learning framework to solve the set problem comprises:
traversing each of the Hamiltonian components in the Hamiltonian;
for a current Hamiltonian component traversed, calling the quantum program interface to construct a first target program, assigning a value to the first target program, calling the quantum program execution interface to obtain the quantum-state distribution probability, and taking the quantum-state distribution probability obtained as a current expectation value;
updating the total expectation value according to the current expectation value and the ratio coefficient of the Hamiltonian corresponding to the current expectation value; and
obtaining an updated total expectation value until all the Hamiltonian components are traversed.

8. The method for constructing a quantum machine learning framework according to claim 6, wherein the Hamiltonian is a linear combination of a plurality of Hamiltonian components, each of the Hamiltonian components having a ratio coefficient, and when the target computed value is a total gradient value;
with respect to the set problem, calling the gradient solving interface provided on the quantum-operation node class inserted into the preset machine learning framework to solve the set problem comprises:
traversing the Hamiltonian components in the Hamiltonian;
for a current Hamiltonian component traversed, determining variational quantum gates containing a specific gradient solving parameter in the variational quantum circuit, and traversing the variational quantum gates;
for a current variational quantum gate traversed, calling the quantum program interface to generate the quantum program, and obtaining a current gradient value corresponding to the current variational quantum gate according to the quantum program;
updating a gradient value corresponding to the current Hamiltonian component according to the current gradient value of the current variational quantum gate until each variational quantum gate is traversed, and taking the gradient value corresponding to the current Hamiltonian component as a current first gradient value; and
updating the total gradient value according to the first gradient value and the ratio coefficient of the Hamiltonian component corresponding to the first gradient value.

9. The method for constructing a quantum machine learning framework according to claim 8, wherein for the current variational quantum gate traversed, calling the quantum program interface to generate the quantum program, and obtaining the current gradient value corresponding to the current variational quantum gate according to the quantum program comprise:
calling the quantum program interface according to a rule that a parameter of the current variational quantum gate increases in a forward direction and decreases in a backward direction to construct two second target programs, respectively, assigning a value to each of the two second target programs, calling the quantum program execution interface to obtain each quantum-state distribution probability, and processing the each quantum-state distribution probability obtained, so as to obtain the current gradient value corresponding to the current variational quantum gate.

10. The method for constructing a quantum machine learning framework according to claim 9, wherein calling the quantum program interface according to the rule that the parameter of the current variational quantum gate increases in the forward direction and decreases in the backward direction to construct the two second target programs, respectively, comprises:
for the current variational quantum gate traversed, according to the rule that the parameter of the current variational quantum gate increases in the forward direction, calling the quantum program interface to construct one of the second target programs according to the quantum bit to be measured, the Hamiltonian and the variational quantum circuit obtained by adding π/2 to the specific gradient solving parameter of the current variational quantum gate; and
for the current variational quantum gate traversed, according to the rule that the parameter of the current variational quantum gate decreases in the backward direction, calling the quantum program interface to construct the other one of the second target programs according to the quantum bit to be measured, the Hamiltonian and the variational quantum circuit obtained by subtracting π/2 from the specific gradient solving parameter of the current variational quantum gate.

11-13. (canceled)

14. A quantum computer, comprising a storage device, a classic processor, a quantum processor, and a program stored in the storage device and operable on the classic processor and the quantum processor, wherein the classic processor runs the program in combination with the quantum processor, to implement:
with respect to a set problem, obtaining a Hamiltonian corresponding to the set problem;
obtaining a number of quantum bits required by the set problem, and obtaining target bits according to the number of the quantum bits;
obtaining a variational quantum circuit of the set problem according to the target bits and the Hamiltonian;
determining a quantum bit to be measured from the target bits, and constructing a quantum-operation node class that provides an expectation-value solving interface and a gradient solving interface according to the quantum bit to be measured and the variational quantum circuit; and
with respect to the set problem, calling the gradient solving interface and the expectation-value solving interface provided on the quantum-operation node class inserted into a preset machine learning framework to solve the set problem, so as to construct the quantum machine learning framework.

15. A non-transient computer storage medium having stored therein a program that when executed by a classic processor of a quantum computer in combination with a quantum processor of the quantum computer to perform a method for constructing a quantum machine learning framework, the method comprising:
with respect to a set problem, obtaining a Hamiltonian corresponding to the set problem;
obtaining a number of quantum bits required by the set problem, and obtaining target bits according to the number of the quantum bits;
obtaining a variational quantum circuit of the set problem according to the target bits and the Hamiltonian;
determining a quantum bit to be measured from the target bits, and constructing a quantum-operation node class that provides an expectation-value solving interface and a gradient solving interface according to the quantum bit to be measured, the Hamiltonian and the variational quantum circuit; and
with respect to the set problem, calling the gradient solving interface and the expectation-value solving interface provided on the quantum-operation node class inserted into a preset machine learning framework to solve the set problem, so as to construct the quantum machine learning framework.

16. The quantum computer according to claim 14, wherein obtaining the Hamiltonian corresponding to the set problem comprises:
decoding-encoding the set problem to a ground state of the Hamiltonian of the set problem, so as to convert the set problem into solving the ground state of the Hamiltonian of the set problem.

17. The quantum computer according to claim 14, wherein the Hamiltonian is obtained by linear superposition of at least one Hamiltonian component; and
obtaining the number of the quantum bits required by the set problem comprises:
counting the number of the quantum bits required according to a serial number of the quantum bit at the bottom right corner of a quantum operator in each Hamiltonian component.

18. The quantum computer according to claim 14, wherein obtaining the variational quantum circuit of the set problem according to the target bits and the Hamiltonian comprises:
obtaining a quantum operator corresponding to the Hamiltonian as a target operator; and
constructing the variational quantum circuit according to the target bits, the target operator and a preset quantum gate converter, in which upon receiving the target operator, the preset quantum gate converter obtains a matrix corresponding to the target operator, converts the matrix into a group of preset basic vectors, and obtains a plurality of quantum gates corresponding to the group of preset basic vectors, so as to convert the target operator into the variational quantum circuit.

19. The quantum computer according to claim 18, wherein the quantum gate is a quantum gate containing a fixed parameter or a quantum gate containing a variable parameter, and the variational quantum circuit comprises the quantum gate containing the fixed parameter and at least one quantum gate containing the variable parameter.

20. The quantum computer according to claim 14, wherein constructing the quantum-operation node class that provides the expectation-value solving interface and the gradient solving interface according to the quantum bit to be measured, the Hamiltonian and the variational quantum circuit comprises:
generating a quantum program interface according to the quantum bit to be measured, the Hamiltonian and the variational quantum circuit, in which a quantum program provided by the quantum program interface comprises a measurement operation instruction aiming at the quantum bit to be measured;
generating a quantum program execution interface according to a quantum-state distribution probability obtained from the quantum program being loaded and operated to perform quantum computing until the measurement operation instruction in the quantum program is executed; and
generating an interface for obtaining a target computed value of the quantum-operation node class according to the quantum-state distribution probability, in which the target computed value is a gradient value or an expectation value.

21. The quantum computer according to claim 20, wherein the Hamiltonian is a linear combination of a plurality of Hamiltonian components, each of the Hamiltonian components having a ratio coefficient, and when the target computed value is a total expectation value:
with respect to the set problem, calling the expectation-value solving interface provided on the quantum-operation node class inserted into the preset machine learning framework to solve the set problem comprises:
traversing each of the Hamiltonian components in the Hamiltonian;
for a current Hamiltonian component traversed, calling the quantum program interface to construct a first target program, assigning a value to the first target program, calling the quantum program execution interface to obtain the quantum-state distribution probability, and taking the quantum-state distribution probability obtained as a current expectation value;
updating the total expectation value according to the current expectation value and the ratio coefficient of the Hamiltonian corresponding to the current expectation value; and
obtaining an updated total expectation value until all the Hamiltonian components are traversed,
when the target computed value is a total gradient value:
with respect to the set problem, calling the gradient solving interface provided on the quantum-operation node class inserted into the preset machine learning framework to solve the set problem comprises:
traversing the Hamiltonian components in the Hamiltonian;
for a current Hamiltonian component traversed, determining variational quantum gates containing a specific gradient solving parameter in the variational quantum circuit, and traversing the variational quantum gates;
for a current variational quantum gate traversed, calling the quantum program interface to generate the quantum program, and obtaining a current gradient value corresponding to the current variational quantum gate according to the quantum program;
updating a gradient value corresponding to the current Hamiltonian component according to the current gradient value of the current variational quantum gate until each variational quantum gate is traversed, and taking the gradient value corresponding to the current Hamiltonian component as a current first gradient value; and
updating the total gradient value according to the first gradient value and the ratio coefficient of the Hamiltonian component corresponding to the first gradient value.

22. The quantum computer according to claim 21, wherein for the current variational quantum gate traversed, calling the quantum program interface to generate the quantum program, and obtaining the current gradient value corresponding to the current variational quantum gate according to the quantum program comprise:
calling the quantum program interface according to a rule that a parameter of the current variational quantum gate increases in a forward direction and decreases in a backward direction to construct two second target programs, respectively, assigning a value to each of the two second target programs, calling the quantum program execution interface to obtain each quantum-state distribution probability, and processing the each quantum-state distribution probability obtained, so as to obtain the current gradient value corresponding to the current variational quantum gate.

23. The quantum computer according to claim 22, wherein calling the quantum program interface according to the rule that the parameter of the current variational quantum gate increases in the forward direction and decreases in the backward direction to construct the two second target programs, respectively, comprises:
for the current variational quantum gate traversed, according to the rule that the parameter of the current variational quantum gate increases in the forward direction, calling the quantum program interface to construct one of the second target programs according to the quantum bit to be measured, the Hamiltonian and the variational quantum circuit obtained by adding π/2 to the specific gradient solving parameter of the current variational quantum gate; and
for the current variational quantum gate traversed, according to the rule that the parameter of the current variational quantum gate decreases in the backward direction, calling the quantum program interface to construct the other one of the second target programs according to the quantum bit to be measured, the Hamiltonian and the variational quantum circuit obtained by subtracting π/2 from the specific gradient solving parameter of the current variational quantum gate.
